(19) United States
(12) Patent Application Publication
(10) Pub. No.: US 2024/0334707 A1
(43) Pub. Date: Oct. 3, 2024

(54) HIGH VOLTAGE DEVICE AND METHOD

(71) Applicant: Micron Technology, Inc., Boise, ID (US)

(72) Inventors: Uma Sharma, Boise, ID (US); Mandar Suresh Bhoir, Boise, ID (US); Salil Shashikant Mujumdar, Nanakaramguda (IN)

(21) Appl. No.: 18/621,724

(22) Filed: Mar. 29, 2024

(30) Foreign Application Priority Data
Mar. 31, 2023 (IN) 202311024716

(51) Int. Cl. H10B 43/40; G11C 16/08; H10B 41/40

(52) U.S. Cl. CPC H10B 43/40; H10B 41/40; G11C 16/08

(57) ABSTRACT

Apparatus and methods are disclosed, including transistors, semiconductor devices and systems. Example semiconductor devices and methods include isolation trenches between transistors that include a dielectric layer that includes a fixed charge. Fixed charge dielectric layers enable trench widths that scale smaller than trenches that do not include fixed charge dielectric layers. This allows increases in device density without sacrificing electronic properties of device shown.

### PRIORITY APPLICATION

This application claims the benefit of priority to Indian Patent Application Serial Number 20/231,1024716, filed Mar. 31, 2023, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to transistor structures in complementary metal oxide semiconductor (CMOS) devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2 illustrates a top view of a portion of a memory device in accordance with some example embodiments.

FIG. 3 illustrates an isometric view of the portion from FIG. 2 in accordance with some example embodiments.

FIG. 4A illustrates a cross section view of a portion of a memory device in accordance with some example embodiments.

FIG. 4B illustrates another cross section view of a portion of a memory device in accordance with some example embodiments.

FIG. 4C illustrates another cross section view of a portion of a memory device in accordance with some example embodiments.

FIG. 4D illustrates another cross section view of a portion of a memory device in accordance with some example embodiments.

FIG. 4E illustrates another cross section view of a portion of a memory device in accordance with some example embodiments.

FIG. 5 illustrates a plot of breakdown voltages between devices at various isolation structure widths in accordance with some example embodiments.

FIG. 6 illustrates an example method flow diagram in accordance with other example embodiments.

FIG. 7 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

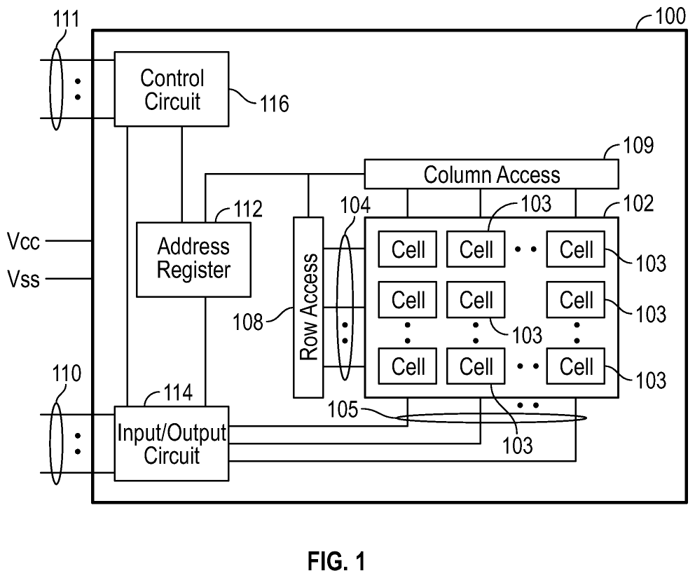

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

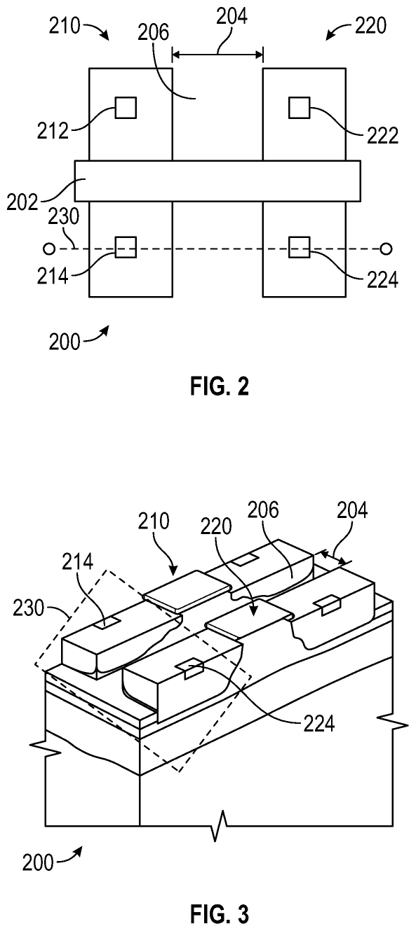

Memory cells 103 and other circuits 114, 116, etc. may include transistors and utilize methods as described in more detail in FIGS. 2-7. In one example, memory arrays 102 include NAND storage array, and peripheral circuits such as circuits 114, 116, 108, 109, etc. may include transistors as described in more detail in FIGS. 2-7. One example of a peripheral circuit that utilizes transistors as described includes a string driver circuit, although the invention is not so limited.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art will recognize that memory device 100 may include other elements, several of which are not shown in FIG. 1, so as not to obscure the example embodiments described herein.

FIG. 2 shows a portion of a peripheral memory circuit 200 that includes two adjacent transistors. The peripheral memory circuit 200 may be included as part of a memory device 100 as described in FIG. 1. A first transistor 210 includes a first source/drain contact 212 and a second source/drain contact 214. A second transistor 220 includes a first source/drain contact 222 and a second source/drain contact 224. In the example shown, a gate line 202 is included that couples to gates of both the first transistor 210 and the second transistor 220. An isolation trench 206 is located between the first transistor 210 and the second transistor 220. In one example, the isolation trench 206 is first etched, or otherwise formed, and is later filled with a dielectric material, such as silicon oxide.

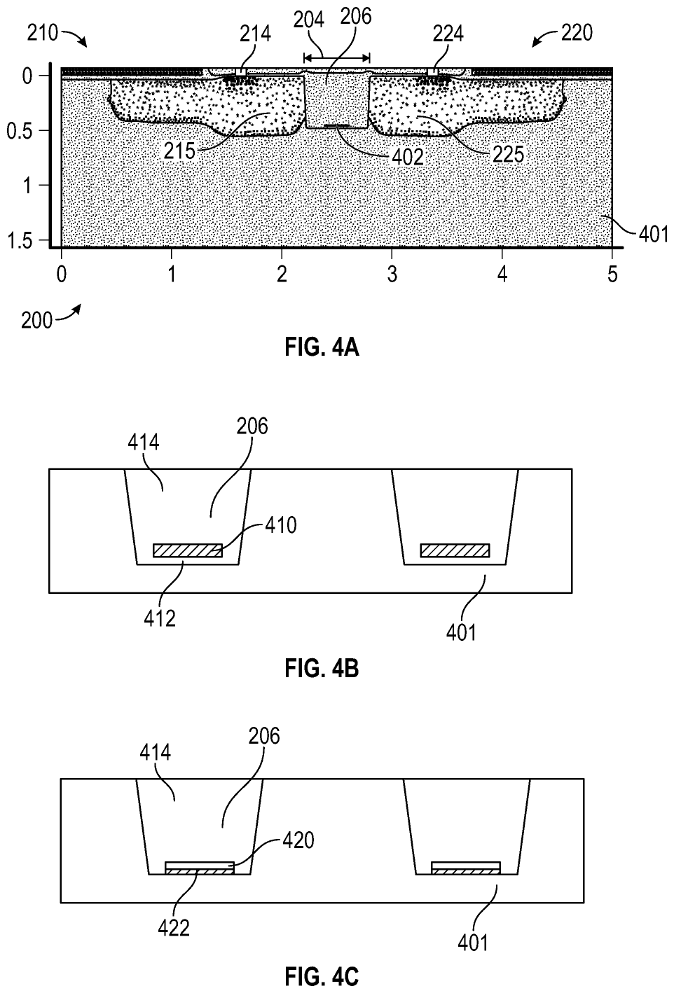

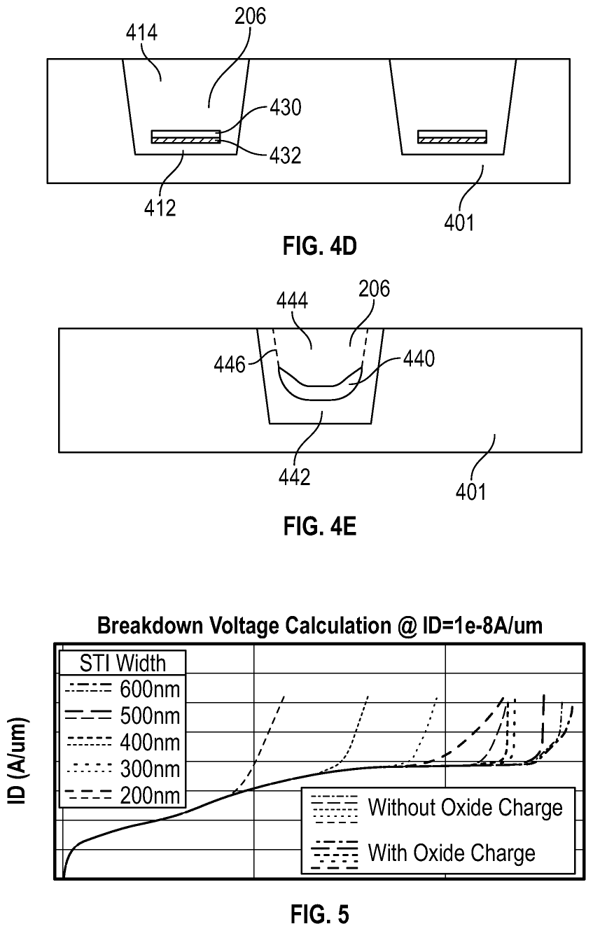

The first transistor 210 is separated laterally from the second transistor 220 by a distance 204 that may also be referred to as a shallow trench isolation (STI) width. Line 230 indicates a cross section that is further illustrated in FIG. 4, and discussed in more detail below.

FIG. 3 shows an isometric view of the portion of a peripheral memory circuit 200 from FIG. 2. As can be seen from the example of FIG. 3, one configuration includes flat transistors such as first transistor 210 and second transistor 220. Other transistor configurations such as vertical transistors, etc. are also within the scope of the invention. The trench 206 is shown with the distance 204 indicated. A dielectric filler oxide is omitted in FIG. 3 to better illustrate the trench 206. The cross section 230 is further illustrated as a plane in FIG. 3 to better show the cross section of FIG. 4A.

FIG. 4A shows the first transistor 210 and the second transistor 220 formed in a semiconductor substrate 401, and separated by the trench 206. A charged dielectric 402 is shown in the trench. In the example shown, the charged dielectric 402 is located in a bottom of the trench, and centered in the trench, however, the invention is not so limited. Distance scales on the X and Y axis are given in micrometers. The trench 206 shown in FIG. 4A is approximately 600 nm in width, although the invention is not so limited. As described in more detail below, the presence of the charged dielectric 402 allows the width 204 to be smaller for a given breakdown voltage requirement than a trench 206 without a charged dielectric 402. In one mechanism of operation, the presence of the charged dielectric 402 significantly increases a voltage needed before depletion begins to occur beneath the trench 206. One circuit in particular that can benefit from these properties is a string driver for NAND memory arrays due to high voltage operation. Other memory driver circuits can also benefit from the addition of a fixed charge dielectric layer as described in selected examples.

In one example, the charged dielectric 402 is formed from a dielectric that includes a fixed charge. In one example, the fixed charge is formed from an induced dipole charge. Examples of dielectrics include, but are not limited to oxides of lanthanum, aluminum, yttrium, and hafnium. Other charged dielectrics that are not oxides are also within the scope of the invention. The presence of a charge, in the charged dielectric 402 provides an electrostatic force that increases the voltage needed before depletion begins to occur beneath the trench 206.

Including the charge in a dielectric, as opposed to a conductor, provides a number of advantages. One advantage includes the more stable and fixed nature of the charge in a dielectric as compared to a conductor. In a conductor, the charge behaves like a floating body, and unwanted dissipation of the charge to an adjacent structure is possible. In a dielectric material, the charge in the charged dielectric 402 is at least partially a result of the material structure, not free electrons. This provides greater stability to the charge in a charged dielectric 402.

Another advantage of a charged dielectric 402 includes improved ability to scale the charged dielectric 402 to very small dimensions. In contrast, forming a conductor layer as a floating body requires several atomic layers of thickness to provide an ability to store charge. Smaller scale charged structures are possible in a dielectric material.

In one example, a charge is induced in a dielectric material by layering a first dielectric material in direct contact with a second dielectric material that includes an oxide. The first dielectric material and the second dielectric material will interact at the interface between the two and charge is created. In one example, the charge includes an induced dipole charge. In one example, inducing a dipole charge includes rearranging oxygen atoms from the second dielectric material into the structure of the first dielectric material. An imbalance of oxygen atoms provides a fixed charge at or adjacent to the interface between the first dielectric material and the second dielectric material. In one example an interaction between the first dielectric material and the second dielectric material is further driven by an anneal step that facilitates or otherwise increases an amount of fixed charge. Although oxygen atom arrangement is one example of a mechanism to provide a fixed charge, the invention is not so limited. Other microstructural or nanostructural arrangements of other elements that result in a fixed charge are also within the scope of the invention.

FIG. 4B shows a close up view of a trench similar to trench 206 from FIG. 4A. FIG. 4B shows a bottom dielectric layer 412 over at least a portion of the isolation trench 206 in substrate 401. In the example of FIG. 4B, the bottom dielectric layer 412 is covering at least a portion of a bottom of the trench 206. A first dielectric layer 410 that includes a fixed charge is shown on the bottom dielectric layer 412. In one example, the first dielectric layer 410 includes a metal oxide, although other materials may be used to form the first dielectric layer 410. A second dielectric 414 is formed over the dielectric layer 410 in FIG. 4B. In one example the bottom dielectric layer 412 and the second dielectric 414 are formed in separate operations, but include the same material, such as silicon oxide. Because the bottom dielectric layer 412 and the second dielectric 414 are separately formed, there may be a detectable interface between them. However, in examples where the bottom dielectric layer 412 and the second dielectric 414 are the same material they may appear monolithic.

In the example of FIG. 4B, the first dielectric layer 410 is spaced apart from a bottom portion of the isolation trench by the bottom dielectric layer 412. In one example, the first dielectric layer 410 includes a fixed charge that is substantially homogenous across the first dielectric layer 410.

FIG. 4C shows another close up view of a trench similar to trench 206 from FIG. 4A. In FIG. 4C, a first dielectric layer 420 is deposited over a bottom dielectric layer, and reacted with the bottom dielectric layer to form a fixed charge region 422 as a reaction product between a bottom dielectric layer that is consumed, and the first dielectric layer 420. In the example of FIG. 4C, a portion of the first dielectric layer 420 remains, while the fixed charge region 422 forms a direct interface with a bottom surface of the trench 206. Similar to the example of FIG. 4B, a second dielectric 414 is formed over the first dielectric layer 420.

FIG. 4D shows another close up view of a trench similar to trench 206 from FIG. 4A. In FIG. 4D, a first dielectric layer 430 is deposited over a bottom dielectric layer 412 and reacted with the bottom dielectric layer to form a fixed charge region 432 as a reaction product between a bottom dielectric layer, and the first dielectric layer 430. In the example of FIG. 4D, a portion of the first dielectric layer 430 remains, and a portion of the bottom dielectric layer 412 remains. The fixed charge region 432 is spaced apart from a bottom surface of the trench 206 by the remaining portion of the bottom dielectric layer 412. Similar to the example of FIG. 4B, a second dielectric 414 is formed over the first dielectric layer 430.

FIG. 4E shows another close up view of a trench similar to trench 206 from FIG. 4A in substrate 401. FIG. 4E shows a bottom dielectric layer 442 over at least a portion of the isolation trench 206. In the example of FIG. 4E, the bottom dielectric layer 442 is covering a bottom of the trench 206, and sides of the trench 206. In deposition operations, while a bottom of trench 206 may be more quickly coated sides may also be coated. A first dielectric layer 440 that includes a fixed charge is shown on the bottom dielectric layer 442. The first dielectric layer 440 of FIG. 4E is shown covering the bottom dielectric layer 442 in a bottom of the trench 206 and some portion of sides of the trench 206. The first dielectric layer 440 may also include an upward facing arc configuration as illustrated in FIG. 4E. An upward facing arc configuration is also possible in other examples such as FIGS. 4B-4D. Different amounts of sidewall coverage of the first dielectric layer 440 are within the scope of the invention. Depending on fabrication methods and conditions, the first dielectric layer 440 may cover only a bottom portion of the trench 206, may cover a bottom and all sidewalls of the trench 206, or may cover the bottom and portions of sidewalls of the trench 206.

FIG. 4E further shows an additional dielectric 444 similar to the additional dielectric 414 from FIGS. 4B-4D. In the example of FIG. 4E, an interface 446 between the additional dielectric 444 and the bottom dielectric layer 442 is shown. As noted above, the interface 446 may be detectable, in selected examples, and may not be detectable in others, depending on material choices with the bottom dielectric layer 442, the additional dielectric 444, and fabrication methods used.

FIG. 5 shows a simulated plot of breakdown voltages of different isolation trench widths (STI width) for configurations without a fixed charge dielectric layer and with a fixed charge dielectric layer as described in examples of the present disclosure. As can be seen from the plot, the inclusion of a fixed charge dielectric layer significantly increases a breakdown voltage over similar STI widths that do not have a fixed charge dielectric layer. Due to the enhanced properties of fixed charge dielectric layers, in one example an isolation trench with a width of 300 nm includes a breakdown voltage of greater than 20 volts. In one example an isolation trench with a width of 200 nm includes a breakdown voltage of greater than 20 volts. In one example an isolation trench depth can also be reduced. In one example, a trench depth is less than or equal to 480 nm. In one example, a trench depth is less than or equal to 380 nm. In addition to providing the ability to narrow isolation trenches, configurations that incorporate a dielectric layer including a fixed charge as described provide improvements in transistor voltage modulation with back bias on channels.

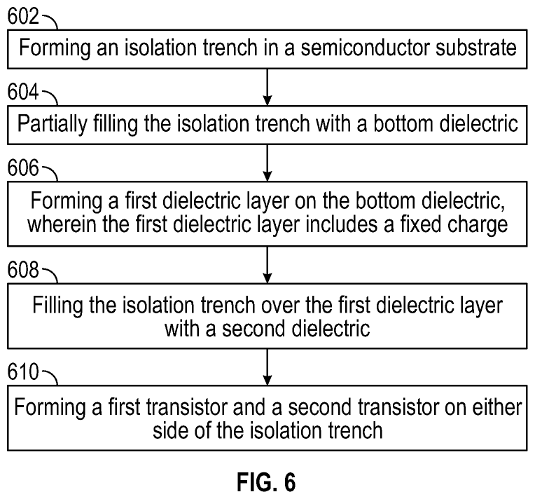

FIG. 6 shows a flow diagram of one example method of manufacture. In operation 602 an isolation trench is formed in a semiconductor substrate. In operation 604, the isolation trench is partially filled with a bottom dielectric. In operation 606, a first dielectric layer is formed on the bottom dielectric, wherein the first dielectric layer includes a fixed charge. In operation 608, the isolation trench is filled over the first dielectric layer with a second dielectric, and in operation 610, a first transistor and a second transistor are formed on either side of the isolation trench.

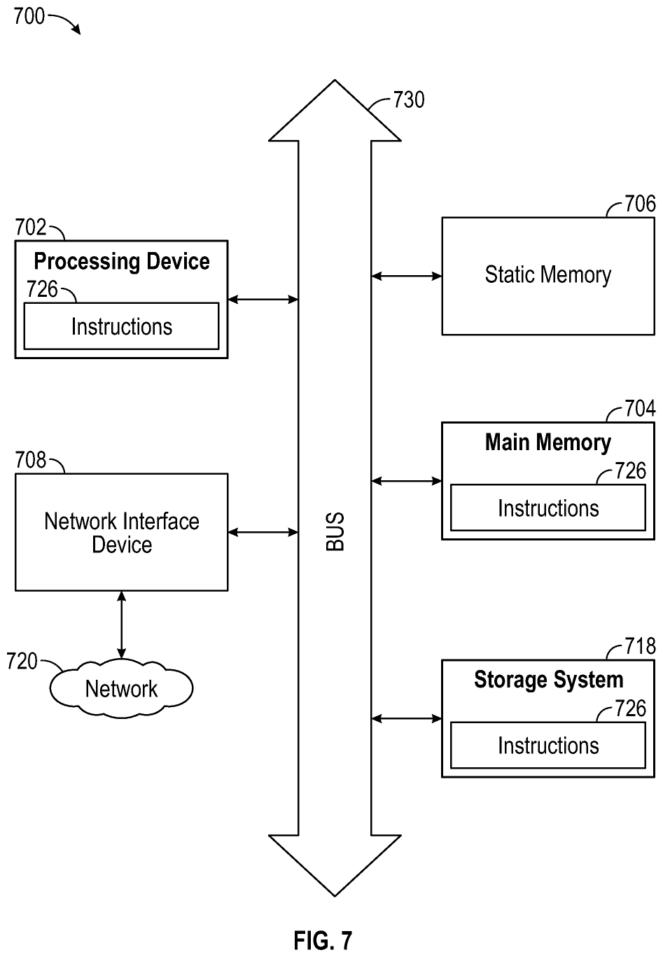

FIG. 7 illustrates a block diagram of an example machine (e.g., a host system) 900 which may include one or more transistors, memory devices and/or memory systems as described above. As discussed above, machine 700 may benefit from enhanced memory performance from use of one or more of the described transistor structures and/or memory systems, facilitating improved performance of machine 700 (as for many such machines or systems, efficient reading and writing of memory can facilitate improved performance of a processor or other components that machine, as described further below.

In alternative embodiments, the machine 700 may operate as a standalone device or may be connected (e.g., networked) to other machines. In a networked deployment, the machine 700 may operate in the capacity of a server machine, a client machine, or both in server-client network environments. In an example, the machine 700 may act as a peer machine in peer-to-peer (P2P) (or other distributed) network environment. The machine 700 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 700 may include a processing device 702 (e.g., a hardware processor, a central processing unit (CPU), a graphics processing unit (GPU), a hardware processor core, or any combination thereof, etc.), a main memory 704 (e.g., read-only memory (ROM), dynamic random-access memory (DRAM) such as synchronous DRAM (SDRAM) or Rambus DRAM (RDRAM), etc.), a static memory 706 (e.g., static random-access memory (SRAM), etc.), and a storage system 718, some or all of which may communicate with each other via a communication interface (e.g., a bus) 730. In one example, the main memory 704 includes one or more memory devices as described in examples above.

The processing device 702 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 702 can also be one or more special-purpose processing devices such as an application specific integrated circuit (ASIC), a field programmable gate array (FPGA), a digital signal processor (DSP), network processor, or the like. The processing device 702 can be configured to execute instructions 726 for performing the operations and steps discussed herein. The computer system 700 can further include a network interface device 708 to communicate over a network 720.

The storage system 718 can include a machine-readable storage medium (also known as a computer-readable medium) on which is stored one or more sets of instructions 726 or software embodying any one or more of the methodologies or functions described herein. The instructions 726 can also reside, completely or at least partially, within the main memory 704 or within the processing device 702 during execution thereof by the computer system 700, the main memory 704 and the processing device 702 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 700 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 700 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 726 (e.g., software, programs, an operating system (OS), etc.) or other data are stored on the storage system 718 can be accessed by the main memory 704 for use by the processing device 702. The main memory 704 (e.g., DRAM) is typically fast, but volatile, and thus a different type of storage than the storage system 718 (e.g., an SSD), which is suitable for long-term storage, including while in an “off” condition. The instructions 726 or data in use by a user or the machine 700 are typically loaded in the main memory 704 for use by the processing device 702. When the main memory 704 is full, virtual space from the storage system 718 can be allocated to supplement the main memory 704; however, because the storage system 718 device is typically slower than the main memory 704, and write speeds are typically at least twice as slow as read speeds, use of virtual memory can greatly reduce user experience due to storage system latency (in contrast to the main memory 704, e.g., DRAM). Further, use of the storage system 718 for virtual memory can greatly reduce the usable lifespan of the storage system 718.

The instructions 724 may further be transmitted or received over a network 720 using a transmission medium via the network interface device 708 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 708 may include one or more physical jacks (e.g., Ethernet, coaxial, or phone jacks) or one or more antennas to connect to the network 720. In an example, the network interface device 708 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 700, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:

Example 1 includes a semiconductor memory device. The memory device includes a first transistor and a second transistor formed in a semiconductor substrate of a first conductivity type and an isolation trench laterally separating the first transistor and the second transistor. The memory device also includes a first dielectric layer adjacent to a bottom of the isolation trench, wherein the first dielectric layer includes a fixed charge, and a second dielectric within a remaining portion of the isolation trench.

Example 2 includes the semiconductor memory device of example 1, wherein the fixed charge includes an induced dipole charge that is located at an interface between the first dielectric layer and the second dielectric.

Example 3 includes the semiconductor memory device of any one of examples 1-2, wherein the first dielectric layer covers a bottom portion of the isolation trench.

Example 4 includes the semiconductor memory device of any one of examples 1-3, wherein the first dielectric layer is spaced apart from a bottom portion of the isolation trench by a third dielectric layer.

Example 5 includes the semiconductor memory device of any one of examples 1-4, wherein the first dielectric layer is spaced apart from a bottom and sidewalls of the isolation trench.

Example 6 includes the semiconductor memory device of any one of examples 1-5, wherein the first dielectric layer includes a high-K dielectric.

Example 7 includes the semiconductor memory device of any one of examples 1-6, wherein the high-K dielectric includes lanthanum oxide.

Example 8 includes the semiconductor memory device of any one of examples 1-7, wherein the high-K dielectric includes hafnium oxide.

Example 9 includes the semiconductor memory device of any one of examples 1-8, wherein the first dielectric layer forms a direct interface with a silicon oxide layer.

Example 10 includes the semiconductor memory device of any one of examples 1-9, wherein the second dielectric layer includes silicon oxide.

Example 11 includes the semiconductor memory device of any one of examples 1-10, wherein the first and second transistors are flat transistors.

Example 12 includes a semiconductor memory device. The memory device includes an array of memory strings, and a driver circuit coupled to the array of memory strings. The driver circuit includes a first transistor and a second transistor formed in a semiconductor substrate of a first conductivity type and an isolation trench laterally separating the first transistor and the second transistor. The memory device also includes a first dielectric layer adjacent to a bottom of the isolation trench, wherein the first dielectric layer includes a fixed charge, and a second dielectric within a remaining portion of the isolation trench.

Example 13 includes the semiconductor memory device of example 12, wherein the first dielectric layer is spaced apart from a bottom portion of the isolation trench by a third dielectric layer.

Example 14 includes the semiconductor memory device of any one of examples 12-13, wherein the first dielectric layer is spaced apart from a bottom and sidewalls of the isolation trench.

Example 15 includes the semiconductor memory device of any one of examples 12-14, wherein the first dielectric layer only covers a bottom surface of the isolation trench.

Example 16 includes the semiconductor memory device of any one of examples 12-15, wherein the first dielectric layer covers a bottom surface and a portion of side surfaces of the isolation trench.

Example 17 includes the semiconductor memory device of any one of examples 12-16, wherein the array of memory strings includes NAND memory strings.

Example 18 includes a method of forming a semiconductor device. The method includes forming an isolation trench in a semiconductor substrate, partially filling the isolation trench with a bottom dielectric, forming a first dielectric layer on the bottom dielectric, wherein the first dielectric layer includes a fixed charge, filling the isolation trench over the first dielectric layer with a second dielectric, and forming a first transistor and a second transistor on either side of the isolation trench.

Example 19 includes the method of example 18, wherein forming the first dielectric layer on the bottom dielectric includes annealing to induce a dipole charge as the fixed charge.

Example 20 includes the method of any one of examples 18-19, wherein the bottom dielectric and the second dielectric are both silicon dioxide.

Example 21 includes the method of any one of examples 18-20, wherein forming the first dielectric layer includes depositing lanthanum oxide.

Example 22 includes the method of any one of examples 18-21, wherein partially filling the isolation trench with a bottom dielectric includes oxidizing an exposed surface of the isolation trench within a silicon substrate to form silicon oxide.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A semiconductor memory device, comprising:
a first transistor and a second transistor formed in a semiconductor substrate of a first conductivity type;
an isolation trench laterally separating the first transistor and the second transistor;
a first dielectric layer adjacent to a bottom of the isolation trench, wherein the first dielectric layer includes a fixed charge; and
a second dielectric within a remaining portion of the isolation trench.

2. The semiconductor memory device of claim 1, wherein the fixed charge includes an induced dipole charge that is located at an interface between the first dielectric layer and the second dielectric.

3. The semiconductor memory device of claim 1, wherein the first dielectric layer covers a bottom portion of the isolation trench.

4. The semiconductor memory device of claim 1, wherein the first dielectric layer is spaced apart from a bottom portion of the isolation trench by a third dielectric layer.

5. The semiconductor memory device of claim 1, wherein the first dielectric layer is spaced apart from a bottom and sidewalls of the isolation trench.

6. The semiconductor memory device of claim 1, wherein the first dielectric layer includes a high-K dielectric.

7. The semiconductor memory device of claim 1, wherein the high-K dielectric includes lanthanum oxide.

8. The semiconductor memory device of claim 1, wherein the high-K dielectric includes hafnium oxide.

9. The semiconductor memory device of claim 1, wherein the first dielectric layer forms a direct interface with a silicon oxide layer.

10. The semiconductor memory device of claim 1, wherein the second dielectric layer includes silicon oxide.

11. The semiconductor memory device of claim 1, wherein the first and second transistors are flat transistors.

12. A semiconductor memory device, comprising:
an array of memory strings;
a driver circuit coupled to the array of memory strings, wherein the driver circuit includes;
a first transistor and a second transistor formed in a semiconductor substrate of a first conductivity type;
an isolation trench laterally separating the first transistor and the second transistor;
a first dielectric layer adjacent to a bottom of the isolation trench, wherein the first dielectric layer includes a fixed charge; and
a second dielectric within a remaining portion of the isolation trench.

13. The semiconductor memory device of claim 2, wherein the first dielectric layer is spaced apart from a bottom portion of the isolation trench by a third dielectric layer.

14. The semiconductor memory device of claim 2, wherein the first dielectric layer is spaced apart from a bottom and sidewalls of the isolation trench.

15. The memory device of claim 2, wherein the first dielectric layer only covers a bottom surface of the isolation trench.

16. The memory device of claim 2, wherein the first dielectric layer covers a bottom surface and a portion of side surfaces of the isolation trench.

17. The memory device of claim 10, wherein the array of memory strings includes NAND memory strings.

18. A method of forming a semiconductor device, comprising:
forming an isolation trench in a semiconductor substrate;
partially filling the isolation trench with a bottom dielectric;
forming a first dielectric layer on the bottom dielectric, wherein the first dielectric layer includes a fixed charge;
filling the isolation trench over the first dielectric layer with a second dielectric; and
forming a first transistor and a second transistor on either side of the isolation trench.

19. The method of claim 19, wherein forming the first dielectric layer on the bottom dielectric includes annealing to induce a dipole charge as the fixed charge.

20. The method of claim 19, wherein the bottom dielectric and the second dielectric are both silicon dioxide.

21. The method of claim 19, wherein forming the first dielectric layer includes depositing lanthanum oxide.

22. The method of claim 19, wherein partially filling the isolation trench with a bottom dielectric includes oxidizing an exposed surface of the isolation trench within a silicon substrate to form silicon oxide.
